(19) United States
(12) Patent Application Publication
(10) Pub. No.: US 2008/0043431 A1
(43) Pub. Date: Feb. 21, 2008

(54) Methods and Systems Employing Tailored Dimples to Enhance Heat Transfer

(75) Inventors: Egidio E. Marotta, Bryan, TX (US); Leroy S. Fletcher, College Station, TX (US)

Correspondence Address: CONLEY ROSE, P.C.;David A. Rose, P. O. BOX 3267, HOUSTON, TX, 77253-3267, US

(73) Assignee: THE TEXAS A&M UNIVERSITY SYSTEM, College Station, TX (US)

(21) Appl. No.: 11/839,912

(22) Filed: Aug. 16, 2007

Related U.S. Application Data
(60) Provisional application No. 60/822,602, filed on Aug. 16, 2006.

(51) Int. Cl. H05K 7/20

(52) U.S. Cl. 361/689

(57) ABSTRACT

A heat sink for cooling a heated component, the heat sink comprising a base coupled to the component. In addition, the heat sink comprises at least one thin-walled heat transfer member extending from the base. The heat transfer member comprises an upstream end and a downstream end defined by a fluid flow direction, and a convective surface extending between the upstream end and the downstream end. Further, the convective surface includes a recessed oval dimple having a major axis and a minor axis. The oval dimple is oriented such that its major axis is at an angle θ relative to the fluid flow direction, wherein the angle θ is between 75° and less than 115°.

### CROSS-REFERENCE TO RELATED APPLICATIONS

This application claims benefit of U.S. provisional application Ser. No. 60/882,602 filed Aug. 16, 2006, and entitled “The Use of Tailored Dimples for Microelectronic Cooling,” which is hereby incorporated herein by reference in its entirety.

### STATEMENT REGARDING FEDERALLY SPONSORED RESEARCH OR DEVELOPMENT

Not applicable

### BACKGROUND

1. Field of the Invention

The invention relates generally to devices and methods for improving thermal performance. More particularly, the invention relates to devices and methods employing tailored dimples to enhance thermal performance.

2. Background of the Invention

With the ever-increasing demand for smaller and faster computers and other microelectronic systems, the quest for improved cooling techniques has also increased. In general, as the number of electronic circuits placed on a single chip increases, so does the thermal energy generated by the chip. The miniaturization of electronic systems, with the associated increase in thermal density, is continuing, but the capability for cooling such miniaturized electronic systems has not increased as rapidly. Without sufficient cooling for such microelectronic systems, excessive operating temperatures and thermal failures may result. For the more advanced systems operating at the edge of stability, a relatively small temperature differences such as 0.5 to 1 K can significantly impact performance and system lifetime. In addition to microelectronic applications, emphasis on heat transfer enhancement has also gained greater significance in other technological areas such as macro and micro scale heat exchangers, gas turbine internal airfoil cooling, fuel elements of nuclear power plants, and biomedical devices.

Many conventional approaches to enhancing heat transfer rely on convection. Typically, a relatively cool fluid (e.g., air) is flowed over a relatively warmer component or device to be cooled (e.g., heat sink). Thermal energy in the component is convectively transferred to, and carried away by, the flowing fluid. The thermal performance of such approaches may be improved by increasing the surface area available for convective heat transfer between the warmer component and the cooler fluid, and by managing the growth of the thermal boundary layer, which may be made thinner or partially broken by flow disturbances. Consequently, many conventional systems employ pin-fins, plate fins, protruding ribs (turbulators), louvered fins, offset-strip fins, slit fins, or vortex generators that extend from the component into the fluid flow. As previously described, such protrusions enhance heat transfer by increasing the convective surface area of the component and by reducing or breaking the thermal boundary layer. However, these protrusions also tend to trigger turbulent fluid flow, resulting in increased friction at the boundary layer-component interface and an associated increase in the pressure drop across the component in the fluid flow direction. Increases in friction and/or the pressure drop across the component adversely affect the aerodynamics and overall efficiencies of the system, and increase the work and energy required to maintain sufficient fluid flow across the component. For example, in the case of convectively cooling turbine blades, surface protrusions on the blades may induce excessive pressure losses across the blades leading to increased compressor loads to compensate. Moreover, the separated flow field triggered by some conventional protrusions may result in significant non-uniform cooling, which may lead to detrimental thermal stresses.

As previously described, many conventional devices for convective cooling rely on increasing surface area through the use of fins or protrusions. In general, as heat transfer needs increase, the number and size of the protrusions can be increased to provide the additional surface area sufficient to satisfy the cooling needs. However, as microelectronic devices become faster and smaller, the heat transfer needs continue to increase, while the space limitations increase. In other words, there is less space available to accommodate greater cooling needs. Consequently, simply increasing the number and/or overall size of cooling fins or protrusions in order to increase thermal performance may not be a viable option for such microelectronic devices.

Accordingly, there remains a need in the art for devices and methods to improve thermal performance. Such devices and methods would be particularly well received if they offered the potential to reduce component temperatures, while minimally impacted the overall component size and the pressure drop across the component.

### BRIEF SUMMARY OF SOME OF THE PREFERRED EMBODIMENTS

In accordance with at least one embodiment of the invention, a heat sink for cooling a heated component comprises a base coupled to the component. In addition, the heat sink comprises at least one thin-walled heat transfer member extending from the base. The heat transfer member comprises an upstream end and a downstream end defined by a fluid flow direction, and a convective surface extending between the upstream end and the downstream end. Further, the convective surface includes a recessed oval dimple having a major axis and a minor axis. The oval dimple is oriented such that its major axis is at an angle θ relative to the fluid flow direction, wherein the angle θ is between 75° and less than 115°.

In accordance with other embodiments of the invention, a method for transferring thermal energy comprises providing a thin-walled heat transfer member having an upstream end, a downstream end, and a convective surface extending therebetween. In addition, the method comprises forming a plurality of recessed oval dimples in the convective surface of the heat transfer member, wherein each oval dimple has a major axis and a minor axis. Further, the method comprises heating the heat transfer member. Moreover, the method comprises flowing a fluid at a Reynolds number between 350 and 1000 in a flow direction over the convective surface from the upstream end towards the downstream end. Still further, the method comprises positioning each oval dimple such that its major axis is oriented at an angle θ relative to the flow direction, wherein the angle θ is between 75° and 115°.

Thus, embodiments described herein comprise a combination of features and advantages intended to address various shortcomings associated with certain prior devices. The various characteristics described above, as well as other features, will be readily apparent to those skilled in the art upon reading the following detailed description of the preferred embodiments, and by referring to the accompanying drawings.

### BRIEF DESCRIPTION OF THE DRAWINGS

For a detailed description of the preferred embodiments of the invention, reference will now be made to the accompanying drawings in which:

FIG. 1 is a perspective view of an embodiment of a heat sink;

FIG. 2 is a partial front view of one of the heat transfer members of the heat sink of FIG. 1;

FIG. 3 is an enlarged partial view of a plurality of the dimples of FIG. 2;

FIG. 4 is a partial cross-sectional view of one of the dimples of FIG. 3 taken along line A-A;

FIGS. 5a-5e are front and partial cross-sectional views of the dimples tested in EXAMPLE 2;

FIG. 6 is a perspective view of the test section employed in the experiments described in EXAMPLE 3;

FIGS. 7a-7c are perspective views of the test specimen, and front and partial cross-sectional views of the dimples included on each test specimen tested in the experiment described in Example 3;

FIG. 8 is a cross-sectional side view of the test section of FIG. 6 illustrating the location of thermocouples in a test specimen tested in the experiment described in EXAMPLE 3;

FIG. 9 is a cross-sectional end view of the test section of FIG. 6 illustrating the location of thermocouples in a test specimen tested in the experiment described in EXAMPLE 3;

FIG. 10a is a side view of the computation grid used for the circular dimples in the numerical analysis described in EXAMPLE 4;

FIG. 10b is a top view of the computation grid used for the circular dimples in the numerical analysis described in EXAMPLE 4;

FIG. 11a is a side view of the computation grid used for the oval dimples in the numerical analysis described in EXAMPLE 4;

FIG. 11b is a top view of the computation grid used for the oval dimples in the numerical analysis described in EXAMPLE 4;

FIG. 12 is a graphical representation of the Heat Transfer Coefficient vs. Reynolds number for the numerical analysis described in EXAMPLE 4;

FIG. 13 is a graphical representation of the Friction Factor Ratio vs. Reynolds number for the numerical analysis described in EXAMPLE 4;

FIG. 14 is a graphical representation of the Thermal Performance Factor vs. Reynolds number for the numerical analysis described in EXAMPLE 4;

FIGS. 15a and 15b are perspective views of the circular dimple analyzed in the numerical model described in EXAMPLE 4; and

FIGS. 16a and 16b are perspective views of the oval dimple analyzed in the numerical model described in EXAMPLE 4.

### DETAILED DESCRIPTION OF THE PREFERRED EMBODIMENTS

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Certain terms are used throughout the following description and claims to refer to particular features or components. As one skilled in the art will appreciate, different persons may refer to the same feature or component by different names. This document does not intend to distinguish between components or features that differ in name but not function. The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection, or through an indirect connection via other devices and connections.

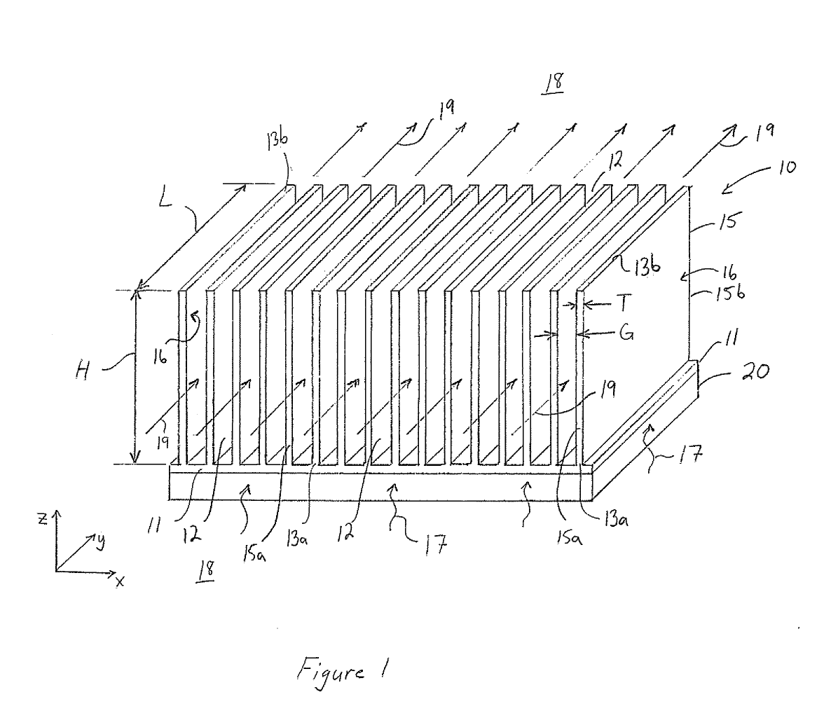

To aid in understanding the descriptions that follow, x-, y-, and z-coordinate axes are shown in FIG. 1. The orientation of the set of coordinate axes (x-, y-, and z-axes) is consistently maintained throughout although different views may be presented.

Referring now to FIG. 1, an embodiment of a heat sink 10 configured to absorb and dissipate thermal energy (i.e., heat) from a component 20 is shown. Component 20 may comprise any device or part that generates thermal energy. For example, component 20 may be a computer processor.

Heat sink 10 comprises a base 11 and a plurality of heat transfer members 15 extending perpendicularly from base 11. The lower surface of base 11 is positioned in contact with component 20. The interfacing surfaces between base 11 and component 20 are preferably smooth and flat to reduce thermal interface resistance and enhance conductive heat transfer therebetween.

In this embodiment, each heat transfer member 15 is a substantially flat, thin-walled fin or plate having a fixed end 13a connected with base 11 and a free end 13b distal base 11. In this embodiment, each fixed end 13a is integral with base 11. In addition, each heat transfer member 15 has an upstream end 15a and a downstream end 15b defined by a flow direction (represented by arrows 19) of a working or cooling fluid 18 flowed across heat transfer members 15.

In this embodiment, each heat transfer member 15 is substantially the same. In particular, each heat transfer members 15 has a wall thickness T, a length L measured between ends 15a, b, and a height H measured between ends 13a, b. The height H and length L of each heat transfer member 15 is substantially greater than its thickness T. Thus, as used herein, the term “thin-walled” may be used to refer to a body or component that has a length and width substantially greater than its sickness. As will be described in more detail below, the relatively large surfaces of heat transfer members 15 extending between ends 15a, b and lying in planes generally perpendicular to the x-axis are adapted to convectively transfer thermal energy to a relatively cooler fluid 18 flowing in the flow direction represented by arrows 19 between adjacent heat transfer members 15. Consequently, such surfaces may also be referred to herein as “convective surfaces”.

Heat transfer members 15 are arranged substantially parallel to each other, but spaced apart by a uniform gap G. As a result, convective surfaces 16 of adjacent heat transfer members 15 define a plurality of flow channels or passages 12. Each flow channel 12 has a height H, a length L, and a width G.

In operation, thermal energy represented by arrows 17 is generated by component 20. Without a means or method to remove this thermal energy from component 20, the temperature of component 20 will steadily increase. Without a sufficient means of removing excessive thermal energy from component 20, it may become thermally damaged and/or rendered inoperable. In other words, the excessive heat that builds up in component 20 may damage component 20. However, heat sink 10 is provided to remove and dissipate excessive thermal energy from component 20. In particular, thermal energy 17 is transferred by conduction from component 20 to base 11 coupled thereto. The thermal energy is then transferred by conduction from base 11 to each of the heat transfer members 15 extending from base 11. Thus, thermal energy 17 generated by component 20 is ultimately transferred to heat transfer members 15. To enhance the heat transfer by conduction through heat sink 10 (i.e., from base 11 to heat transfer members 15), each component of heat sink 10 (e.g., base 11 and heat sink members 15) preferably comprises a material with a relatively high thermal conductivity such as aluminum (205 W/mK) or copper (400 W/mK). Aluminum may be particularly preferred because of its relatively low cost, low weight, and ease of manufacturing/machining.

Without a means to dissipate thermal energy from heat transfer members 15, the thermal energy transferred to heat transfer members 15 will increase the temperature of heat transfer members 15. However, a cooling or working fluid 18 is flowed through flow channels 12 and across the convective surfaces 16 of heat transfer members 15 from upstream ends 15a to downstream ends 15b in a flow direction represented by arrows 19. Fluid 18 is preferably characterized by laminar flow, having an associated Reynolds number below 2000, and more preferably between 350 and 1000. The inlet temperature of fluid 18 (i.e., the temperature of fluid 18 before passing through flow channels 12) is preferably less than the temperature of heat transfer members 15, thereby facilitating the convective flow of thermal energy from convective surfaces 16 into fluid 18. As fluid 18 acquires thermal energy from heat transfer members 15, the temperature of fluid 18 will generally increase. Consequently, the outlet temperature of fluid 18 is greater than the inlet temperature of fluid 18. The thermal energy transferred from heat transfer members 15 to fluid 18 is carried away by fluid 18 as it pass through and exits flow channels 12. In this manner, thermal energy 17 generated by component 20 is transferred to, and removed by, fluid 18. In general, cooling fluid 18 may comprise any suitable liquid or gas including, without limitation, air and water.

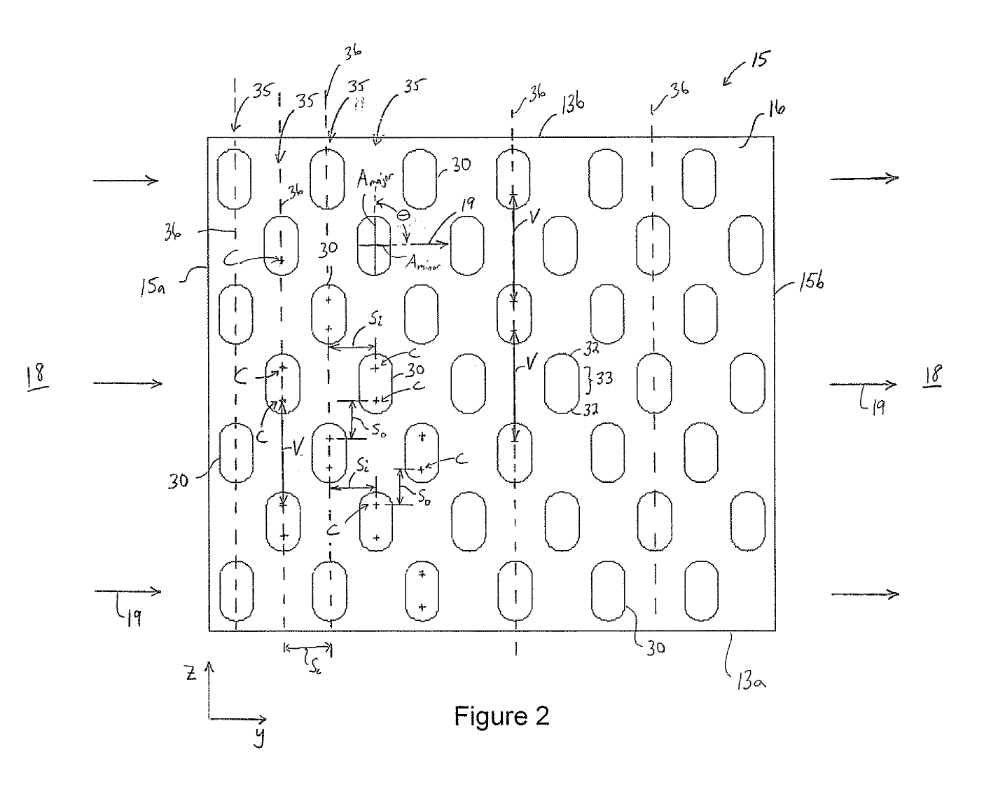

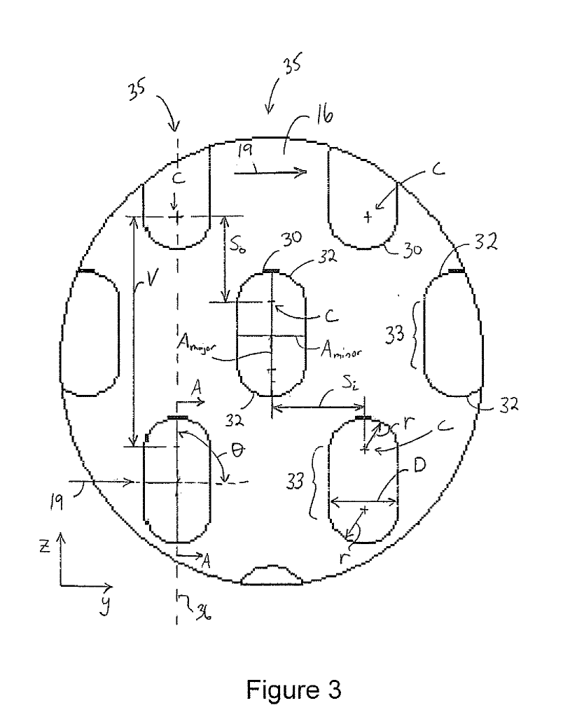

Referring now to FIGS. 2 and 3, each convective surface 16 includes a plurality of indentations or recessed dimples 30. Although only one side of heat transfer member 15 is shown in FIG. 2, in this embodiment, both convective surfaces 16 of heat transfer member 15 include a plurality of dimples 30. In this embodiment, each dimple 30 is non-circular in shape, and more specifically oval in shape. As best shown in FIG. 3, each dimple 30 includes a pair of generally opposed semi-circular ends 32 and a generally rectangular mid-section 33 extending between the semi-circular ends. Each semi-circular end 32 has a center of curvature C and is defined by a radius r and a diameter D. It is to be understood that the diameter D is twice the radius r. Thus, the diameter D defines the diameter of semi-circular ends 32 of each dimple 30, as well as the width of each dimple 30. In this embodiment, diameter D of each dimple 30 is about 0.75 mm.

Each dimple 30 has a major axis Aₘₐⱼₒᵣ along its length and a minor axis Aₘᵢₙₒᵣ, along its width. It is to be understood that axes Aₘₐⱼₒᵣ, Aₘᵢₙₒᵣ are perpendicular. Major axis Aₘₐⱼₒᵣ and minor axis Aₘᵢₙₒᵣ intersect at the geometric center of dimple 30. Each dimple 30 is oriented with its major axis Aₘₐⱼₒᵣ at an angle θ relative to the fluid flow direction 19. Angle θ is preferably between 0° and 180°, more preferably between 75° and 105°, and most preferably about 90°. In this embodiment, each angle θ is about 90°. In other words, each dimple 30 is oriented with its major axis Aₘₐⱼₒᵣ substantially perpendicular to the fluid flow direction 19. In other embodiments, the dimples (e.g., dimples 30) may be arranged with their major axis (e.g., major axis Aₘₐⱼₒᵣ) parallel or at an acute angle relative to the fluid flow direction 19.

Referring now to FIG. 4, each dimple 30 has a maximum depth δ measured perpendicularly from convective surface 16 to the lowermost surface 32 of each dimple 30. Smooth continuously contoured transition surfaces 34 extend between convective surface 16 and lowermost surface 32 of each dimple 30. In this embodiment, dimple depth δ is about 0.15 mm. In general, dimples 30 may be formed in convective surfaces 16 by any suitable means including, without limitation stamping, machining, photolithographic etching, high pressure molding or injection molding, rolling between mandrels, microelectronic machining (MEMS), laser ablation, electronic discharge machining (EDM) or other means depending upon the shape of the desired dimples.

Referring again to FIGS. 2 and 3, dimples 30 may be described as being arranged in a plurality of parallel rows 35. Each row 35 extends linearly between fixed end 13a and free end 13b along a median line 36. In this embodiment, each medial line 36, and hence each row 35, is oriented substantially perpendicular to the fluid flow direction 19. Within each row 35, dimples 30 are arranged with their major axes Aₘₐⱼₒᵣ aligned with, and incident with, medial line 36. Further, within each row 35, adjacent dimples 30 are spaced apart by a distance V measured along median line 36 between the centers of curvature C of the proximal semicircular ends 32 of adjacent dimples 30. In this particular embodiment, distance V between adjacent dimples 30 in each row 35 is substantially the same.

Referring still to FIGS. 2 and 3, dimples 30 in adjacent rows 35 are spaced apart by an inter-row pitch Sᵢ measured perpendicularly between median lines 36 of adjacent rows 35. In this embodiment, pitch Sᵢ is about 0.91 mm. In addition, dimples 30 in adjacent rows 35 are offset relative to each other in the z-direction by an offset pitch Sₒ measured parallel to median lines 36 between centers of curvature C of proximal semi-circular ends 32 of adjacent dimples 30 in adjacent rows 35. In other words, offset pitch Sₒ describes the offset distance between dimples 30 in one row 35 relative to the dimples 30 in an adjacent row 30. In this embodiment, the offset pitch Sₒ between dimples 30 of each pair of adjacent rows 35 is substantially the same. In this embodiment, pitch Sₒ is about 0.91 mm. Thus, in this embodiment, inter-row pitch Sᵢ and offset pitch Sₒ are substantially the same. Such an arrangement of parallel rows (e.g., rows 35) of dimples (e.g., dimples 30), where adjacent rows are offset relative to each other may also be described herein as “staggered”.

The ratio of pitch Sᵢ to dimple diameter D is preferably between 0.80 and 2.00, and more preferably about 1.21. Likewise, the ratio of dimple pitch Sₒ to dimple diameter is preferably between 0.80 and 2.00, and more preferably about 1.21 In this embodiment, pitch Sᵢ and pitch Sₒ are substantially the same. Consequently, in this embodiment, the ratio of the pitch Sᵢ to dimple diameter D, and the ratio of pitch Sₒ to dimple diameters D, are both about 1.21 (0.91 mm/0.75 mm). In addition, the ratio of dimple depth δ to dimple diameter D is preferably about 0.18 to 0.24, and more preferably about 0.20. In this embodiment, the ratio of the dimple depth to dimple diameter D is about 0.20 (0.15 mm/0.75 mm).

As previously described, many conventional approaches to deal with increasing thermal energy outputs by advanced electronic devices involve increasing the size (e.g., length and/or width) of the heat transfer members (e.g., heat transfer members 15), or increasing the number of heat transfer members, thereby increasing the surface area available for convective heat transfer However, as microelectronic devices become more advanced, it is often desirable, at least from a commercial standpoint, to miniaturize and reduce the overall dimensions of such devices. As a result of space limitations, increasing the convective surface area by simply increasing the dimensions of the heat transfer members of the heat sink and/or increasing the number of heat transfer members in the heat sink may not be a viable option. Another alternative may be to transition from a laminar to a turbulent flow regime to enhance heat transfer. However, most microelectronic devices operate with a laminar flow region, and further, turbulent flow regimes often lead to increases in friction and increased pressure drops that may detrimentally affect efficiency.

Embodiments described herein include engineered dimples (e.g., dimples 30) that offer the potential to increase thermal performance without significantly increasing the dimensions of the individual heat transfer members (e.g., heat transfer members 15), and without significant increases in friction and associated increase in pressure drop.

In general, drag force results from the relative motion of an object and a fluid, and has two basic components: (1) form drag caused by the geometry of the object and the pressure differential across the object (i.e., pressure difference upstream and downstream of the object), and (2) skin drag caused by viscous shearing of the fluid at the surface of the object. Without being limited by this or any particular theory, dimples (e.g., dimples 30) generally reduce form drag but tend to increase skin drag. Consequently, in those applications where form drag is the primary component of drag force (e.g., blunt objects, high Reynolds number applications, etc.), dimples may be employed to reduce overall drag force and friction. However, in applications where form drag is negligible as compared to skin drag (e.g., flow inside pipes or over flat walls), dimples generally do not significantly reduce overall drag force and friction. Rather, in some cases dimples may slightly increase skin drag.

Numerical and experimental work has indicated that flow over dimpled surfaces (e.g., convective surface 16) develop vortex-like structures inside and in the wake area of the dimples, thereby slightly increasing skin drag due to inertial and viscous effects in the fluid as compared to a smooth, flat surface. However, numerical and experimental work has also indicated that dimples (e.g., dimples 30) also increase the surface convective heat transfer coefficient. Without being limited by this or any particular theory, the slight increase in skin drag resulting from dimples is generally less than the more significant increases in form drag typically observed in other heat transfer enhancement devices such as rib turbulators and pin fins which protrude into the fluid flow. Without being limited by this or any particular theory, the reasoning for this phenomenon is that fluid motion inside dimples is generally self-organized, and thus, the pressure loss from dimples tends to be less than that observed with turbulence promoters that physically project into the flow, adding form drag. The heat transfer is enhanced because these self-organized vortex structures promote mixing, drawing “cold” fluid from outside the thermal boundary layer into contact with the wall, thus improving convective heat transfer.

Most of the experimental and numerical studies on dimpled surfaces have concentrated on the use of dimples for flow characteristics deemed to be within the turbulent flow regime. Although heat transfer may be enhanced in turbulent flow, turbulent flow regimes often result in increased friction and associated pressure drops losses, which, as described above, may reduce system efficiencies. Laminar flows, which are routinely found in microelectronic cooling packaging, may limit the thermal dissipation performance of heat sinks. Embodiments of specifically engineered dimples (e.g., dimples 30) offer the potential enhance thermal performance without significantly increasing friction in laminar flows.

Numerical and experimental word has indicated that when a dimpled surface is used in a flow channel flow, dimple geometry and orientation play a key role in the heat transfer, friction, and pressure drop across the surface. Thus, the preferred dimple geometry and orientation will be that which provides the greatest heat transfer improvement with the least frictional or drag losses for a specific application. As disclosed in (a) “Optimization of Heat Sink Performance in Microelectronics Through Applied Dimpled Surfaces: Study on Dimple Geometry and Array”, by Silva, Marotta, and Fletcher, 2007 GSRIC Proceedings, ASMPE Graduate Student Research & Innovation Conference, Apr. 13-14, 2007; (b) “Experimental and Numerical Study of Laminar Forced Convection Heat Transfer for a Dimpled Heat Sink”, by Park, Silva, Marotta, and Fletcher, ASME Journal of Electronic Packaging (In Press); and (c) “Flow Structure and Enhanced Heat Transfer in Channel Flow with Dimples Surfaces: Application to Heat Sinks in Microelectronic Cooling,” Silva, C., Marotta, E. E. and Fletcher, L. S., ASME paper No. IMECE2005-50163, International Mechanical Engineering Congress and Exposition, Orlando, Fla., Nov. 5-11, 2005, each of which is hereby incorporated herein by reference in its entirety, it is believed that dimples 30 having the geometric properties described herein offer the potential for a reasonable compromise between thermal performance improvement and friction or drag losses. In particular, embodiments of dimples 30 described herein offer the potential for about a 10% increase in the heat transfer coefficient as compared to a smooth wall, and about a 7% increase in the heat transfer coefficient as compared to circular dimples in substantially the same application. Such improvements in the heat transfer coefficient offer the potential for about a 3 to 5 K temperature reduction as compared to a smooth wall, and 0.5 to 2 K temperature reduction as compared to circular dimples in substantially the same application. Such reductions are potentially significant, particularly in cutting edge microelectronic applications where a difference of 0.5 K can mean the difference between stable operation and excessive heating.

### EXAMPLE 1

To quantify the potential improvement in thermal performance by the use of dimples on a heat sink, a computational fluid dynamics (CFD) modeling process was used to evaluate different dimpled configurations within the laminar flow regime for air as the cooling fluid. In particular, the CFD model was employed to assess the enhancement of heat transfer for an exemplary IBM eServer Blade heat sink coupled to a single microprocessor operating at 100 watts of power. The design parameters for the exemplary IBM eServer Blade heat sink are shown below in Table 1.

TABLE 1
Exemplary IBM eServer Blade Heat
Sink CFD Model Test Parameters

| Heat-Sink Geometry | | | Dimple Geometry | |
|---|---|---|---|---|
| Fin Height H | 10 | mm | Dimple Depth | 0.15 mm |
| Fin Gap G | 1.4 | mm | Dimple Diameter (for | 0.75 mm |
| | | | circular dimples); | |
| | | | Dimple Width (for | |
| | | | oval dimples) | |
| Fin Thickness T | 0.5 | mm | Pitch | 0.95 mm |
| Fin Length L | 125 | mm | Array | 11 × 135 |
| Reynolds Number | 500 | | Dimple Arrangement | Staggered |
| Inlet Cooling Fluid | 300 | K | | |
| Temperature | | | | |

The results of the CFD model applied to (a) the fin with no augmentation (i.e., no dimples), (b) the fin with circular dimples, (c) the fin with oval dimples, and (d) the fin with extended oval dimples (i.e., same width D as in case (c) but with a greater length). The CFD results are summarized in Table 2.

TABLE 2
Exemplary IBM eServer Blade Heat
Sink CFD Model Test Results

| | | Pressure Drop |
|---|---|---|
| Case | Average Fin Temperature | Across the Fin |
| (a) Fin with no augmentation | 314.42 K | 38.8 Pa |
| (i.e., no dimples) | | |
| (b) Fin with circular dimples | 311.95 K | 33.33 Pa |
| (c) Fin with oval dimples | 311.47 K | 34.71 Pa |
| (d) Fin with extended oval | 311.10 K | 36.22 Pa |
| dimples | | |

The results of the CFD model indicated that circular dimples provided a 2° C. to 3° C. improvement in thermal performance as compared to no dimples, whereas the oval dimples provided a 3° C. to 5° C. improvement in thermal performance as compared to no dimples. The circular and oval dimples did not appear to appreciably increase the pressure drop across the fin.

### EXAMPLE 2

To quantify the potential improvement in thermal performance of dimpled heat sink a computational fluid dynamics (CFD) model was developed using FLUENT 6.2.16. The dimensions of the exemplary heat sink fin are shown in Table 3.

TABLE 3
Heat Sink Geometry

| | |
|---|---|
| Fin height | 10 mm |
| Fin gap | 1.4 mm |
| Fin thickness | 0.5 mm |
| Fin length | 125 mm |

Circular dimples, oval dimples, and double dimples were tested in the model. Oval dimples were modeled as circular dimples split diametrically with a rectangular midsection added between the two circular halves. Three midsection sizes were used to obtain three different oval dimples with different aspect ratios. The oval dimples were tested with their long axes (e.g., major axes) aligned both parallel and perpendicular to the cooling fluid flow direction. Double dimples were modeled as circular dimples with a second, smaller dimple in the wake area of each main dimple.

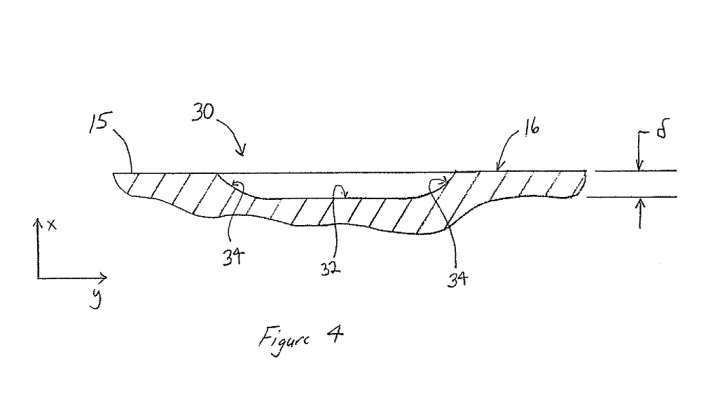

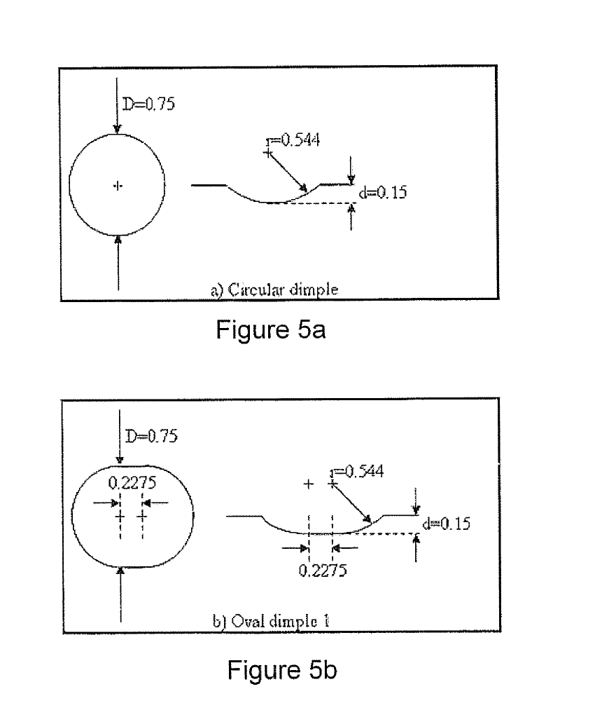

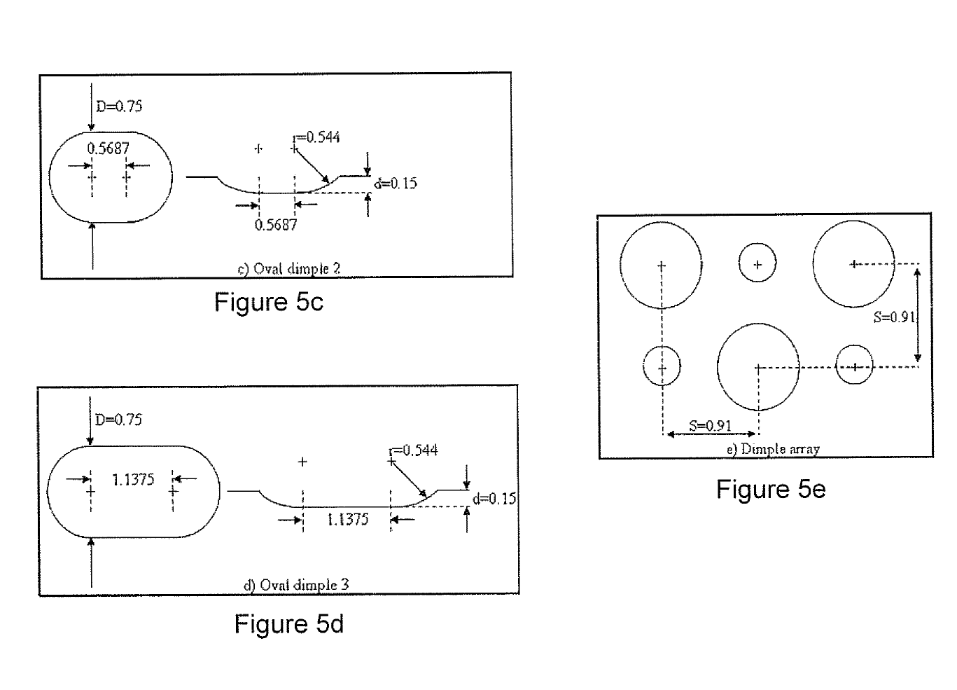

All dimple arrays were staggered with relative pitch S/D=1 21 and a relative depth δ/D=0.2, where S was the dimple pitch, δ was the dimple depth, and D was the dimple diameter. For the oval dimples, the diameter D used for calculating δ/D and S/D was the circular-edge-to-edge distance (i.e., diameter of the semi-circular ends of the oval dimple). Thus, the oval dimples had the same total depth and circular-edge-to-edge distance as the circular dimples. The details of the different dimple geometries and arrays tested are shown in FIGS. 5a to 5e.

The grid used in the CFD model was a structured hexahedral/wedge mesh with a cylindrical array of elements within the dimples. The solver used was the segregated implicit, with SIMPLE formulation for pressure solution and Upwind scheme for momentum and energy equations.

The domain modeled was a single vertical fin/gap pair with symmetry boundary conditions on the fin and gap middle planes. The half-thicknesses of the fin and gap were 0.25 and 0.7 mm respectively. The whole height of the fin was modeled, but only 20 mm of the fin length measured from the gap entrance were considered. The fin was modeled as cooper, with a shroud on top to avoid fluid losses. Fluid was air as an ideal gas, with entrance conditions set as T=300 K and uniform velocity of 5.6 m/s for a Reynolds number of 500 based on gap (channel) height.

Power supply was considered to be 47000 W/m², equivalent to 4-150 W microprocessors mounted on an 11×12 cm quad-core chipset. Heat flux was assumed to come from the base of the test surface, not from the back of the test surface. This rendered a ‘perpendicular’ heat flux direction relative to the direction of the flow, and was intended to offer a more realistic model of the finned heat sink. All other surfaces were considered thermally insulated, with the gap exit modeled as a velocity outflow at atmospheric pressure.

In this work, a 600 k element model was used as a baseline for all the models. The final number of elements varied from 360 k (flat surface) to 896 k elements (double dimple), depending on the number of dimples. All the calculations were performed with an IBM Regatta p690 at the Texas A&M University Supercomputer Facility. Convergence was declared when residual for continuity, velocity and energy reached values of 10⁻⁵, 10⁻⁶ and 10⁻¹², respectively. Simulations converged after 210 to 310 iterations, taking approximately 3 hours each using a single 1.3 GHz processor.

Table 4 shows the area-averaged wall temperature, pressure drop, and specific characteristics of each model simulated. Oval dimples with their long axis aligned with the flow direction were identified as ‘horizontal’, while ‘vertical’ indicates long axis aligned perpendicular to the flow. Only whole dimples were considered in these models, therefore small size differences exist between models (especially in fin height), depending on number of dimples and alignment.

Results showed that circular dimples, double dimples, and oval vertical dimples improved average wall temperature by up to 3.3 K when compared to the flat wall. Horizontal oval dimples offered little to no temperature improvement. Pressure losses were calculated as the difference between the area-averaged static pressures in the inlet and outlet. Pressure drop went up in the dimpled models with the double and vertical oval dimples showing the higher increments (up to 26%) when compare to the flat wall.

TABLE 4
Numerical Modeling Results

| | Average wall T | Pressure drop | No. of elements | | Fin size |
|---|---|---|---|---|---|
| Model | (K) | (Pa) | (10³) | No. of dimples | (L × H, mm) |
| Flat | 314.42 | 28.81 | 361 | — | 20.02 × 10.01 |
| Circular dimple | 311.95 | 33.33 | 602 | 22 × 10 | 20.02 × 10.01 |
| Oval dimple 1-horizontal* | 313.71 | 32.90 | 497 | 18 × 10 | 20.47 × 9.1 |
| Oval dimple 2-horizontal | 314.14 | 31.56 | 475 | 14 × 10 | 20.70 × 9.1 |
| Oval dimple 3-horizontal | 314.39 | 29.84 | 445 | 10 × 10 | 20.47 × 9.1 |
| Double dimple | 311.58 | 35.41 | 896 | 22 × 10 | 20.02 × 10.01 |
| | | | | (both) | |
| Oval dimple 1-vertical | 311.47 | 34.71 | 546 | 22 × 9 | 20.02 × 10.23 |
| Oval dimple 2-vertical | 311.15 | 35.45 | 522 | 22 × 7 | 20.02 × 10.35 |
| Oval dimple 3-vertical | 311.10 | 36.22 | 489 | 22 × 5 | 20.02 × 10.24 |

*Horizontal oval dimples were oriented with their long axis (i.e., major axis) parallel to the direction of cooling fluid flow. Vertical oval dimples were oriented with their long axis (i.e., major axis) perpendicular to the direction of cooling fluid flow.

Based on the numerical results and analysis of the geometries tested, the oval dimple 2-vertical configuration offered the best compromise between heat transfer improvement and friction losses. Table 5 shows the average convective heat transfer coefficient and Nusselt number for the flat plate, circular dimples, and oval dimple 2-vertical. The average convective heat transfer coefficients and Nusselt numbers were calculated using energy balance, area-average wall, inlet and outlet temperatures, and the total area (flat and dimpled area) in each model. Thermal conductivity of air at 303 K and channel half-height of 0.7 mm were considered for the Nusselt number calculation.

TABLE 5
Average Convective Heat Transfer Coefficient -
Numerical Model, Re = 500

| | | | Nu/Nu₀ |
|---|---|---|---|
| Model | h (W/m²K) | Nu | (h/h_{flat}) |
| Flat | 135.05 | 3.652 | — |
| Circular dimple | 141.30 | 3.822 | 1.046 |
| Oval dimple 2-vertical | 150.09 | 4.059 | 1.111 |

In summary, circular dimples showed increased thermal performance as compared to flat plates. Double dimples and oval dimples with the long axis (i.e., major axis) aligned perpendicularly to the flow direction offered improved performance over the circular dimples. For oval dimples with their long axis aligned perpendicular to the flow direction, thermal improvement and friction losses increased as the oval dimples were elongated. For such oval dimples with their long axis aligned parallel to the flow direction showed worse performance than circular dimples (close to flat plates). For oval dimples long axis aligned parallel to the flow direction, thermal improvement and friction losses decreased as dimple were elongated.

### EXAMPLE 3

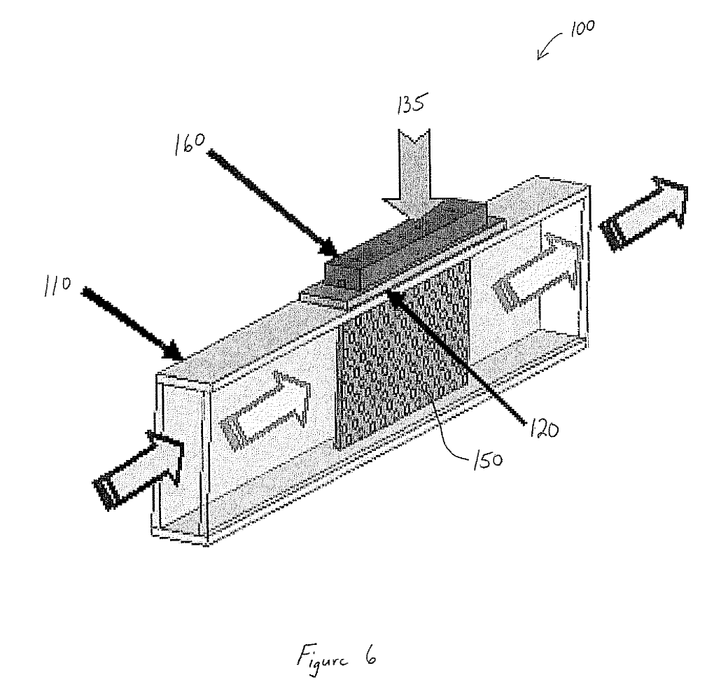

To test and quantify the potential improvement in the thermal performance by employing dimples on a heat sink, controlled experiments were conducted. The test apparatus consisted of an open loop flow circuit including a centrifugal blower, a plenum to stabilize the flow drawn by the blower, a calibrated orifice flow meter, a gate valve, and a test section 100. Referring briefly to FIG. 6, test section 100 included a rectangular flow channel 110 having inner cross section dimensions of 32 mm (wide) and 103.5 mm (height), and a length of about 200.2 mm. Flow channel 110 was constructed with 6.35 mm thick acrylic plates (thermal conductivity k of ˜0.16 W/mK at 20° C.) to facilitate visualization of the setup and to minimize heat losses.

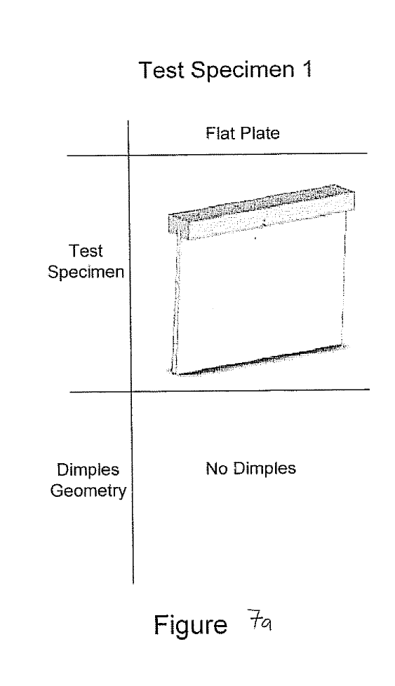

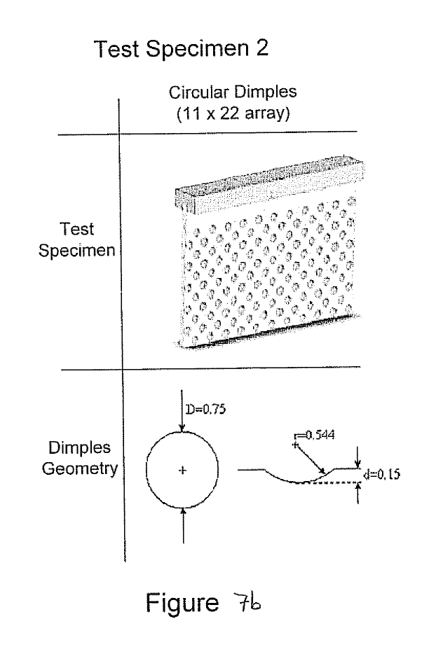

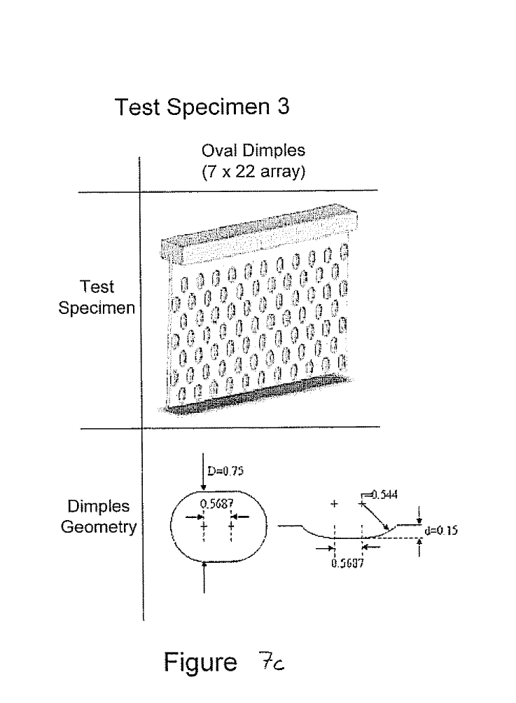

As shown in FIGS. 7a-7c, three different test specimen or plates 150 were tested. The first test specimen 150 was flat and included no dimples. The second test specimen 150 included an 11 by 22 arrangement of circular dimples. The third test specimen 150 included a 7 by 22 arrangement of oval dimples. For the second and the third test specimens 150, the dimples were placed on both sides of the plate with a relative pitch S/D=1 21 and a relative depth δ/D=0.2, where S was the dimple pitch, δ was the dimple depth, D was the dimple diameter. For the oval dimples, the diameter D used for calculating δ/D and S/D was the circular-edge-to-edge distance (i.e., diameter of the semi-circular ends of the oval dimple). Thus, the oval dimples had the same total depth and circular-edge-to-edge distance as the circular dimples. Similar to the oval dimple-2 vertical orientation described above in EXAMPLE 2, the oval dimples shown in the third test specimen 150 of FIG. 7c were oriented with their major axis perpendicular to the direction of flow of the cooling fluids. Each test specimen 150 was fabricated with 5 mm thickness ASTM B152 Electroless Oxygen-Free Copper.

Each test specimen 150 was screwed onto a copper block 160, and then inserted into the vertical flow channel 110. With the test specimen 150 positioned inside the flow channel 110, the flow channel was effectively divided into two 13.5 mm wide, full height channels. Omega electric heaters 130 (model KH-108/5-P Kapton heater, 25.4×203.2 mm, 115 Volts, 40 W total power, pressure sensitive adhesive on one side) were adhered to the upper side of the copper block 160. The heaters 130 provided a heat flux 135 of up to 40 kW/m² through the copper block 160 to the 5 mm thick test specimen 150. Power to heaters 130 was supplied by an Elenco Precision variable power supply model XP-800, with multi-meters TENMA 72-6685A and 72-6185 used to measure voltage and current into the heater.

A 300×300×450 mm plenum and a 2500 mm length channel section were added downstream and upstream of test section 100, respectively, the former to stabilize the flow drawn by the blower and the later to ensure uniform laminar flow over the test specimen 150. In order to reduce fluid impingement and turbulence generation over the leading edge of the test specimen 150, a 5 mm thick acrylic separator was added proximal the channel entrance to test section 100 A 1.5 inch diameter PVC pipe was used from the plenum to the blower, with an ASME-standard orifice plate flowmeter used to determine volumetric air flow and define the Reynolds number. Pressure losses in the test section were not measured in this investigation.

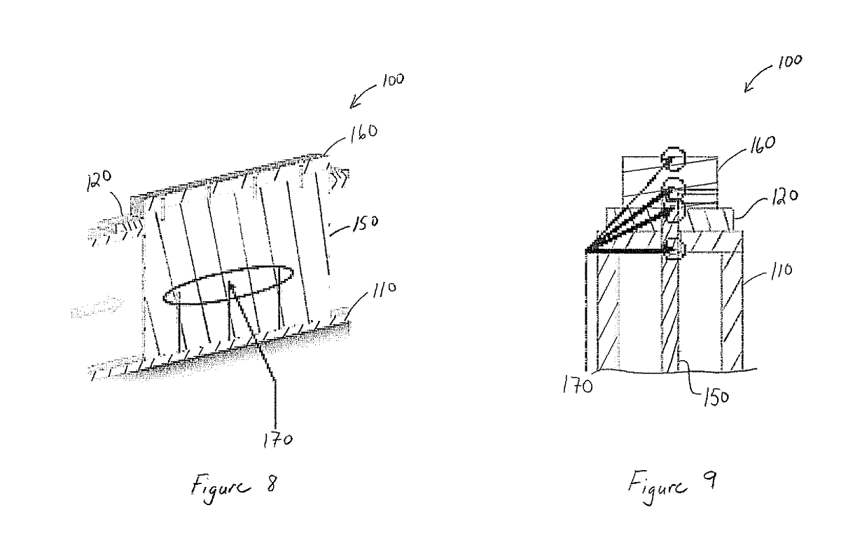

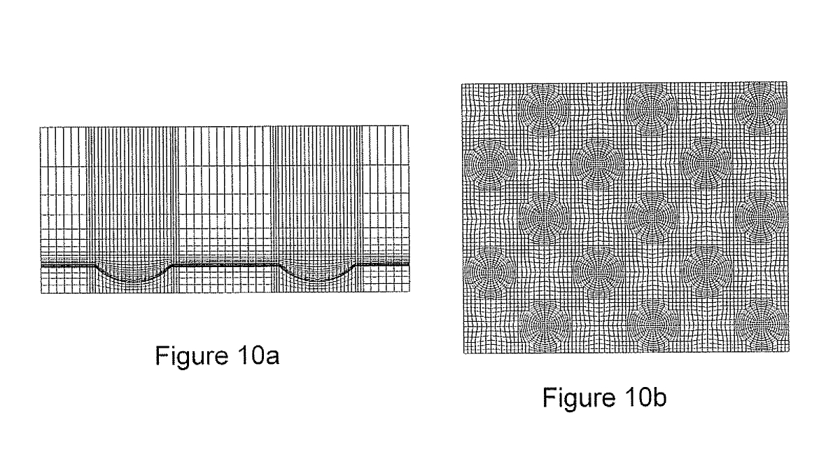

Temperature measurements were made using special limited error gauge-30 T-type thermocouples 170, with a total of 24 thermocouples distributed among the leading, trailing and bottom edge, base and centerline of the test section in every plate as shown in FIGS. 9 and 10. Additional thermocouples were used at the channel inlet and at the ASME orifice plate in order to obtain air inlet temperature and temperature correction for the volumetric air flow. Thermocouples were connected to a National Instruments data acquisition unit model SCXI-1000, and then a PC running Lab view 7.1. Test section 100 was insulated with a 1 inch fiberglass wool, with the heather having a second layer of insulation both on top and between the its base and acrylic wall in the top of the channel, so that the majority of heat flux 135 was conducted through the copper test specimen 150. Heat losses were estimated running no-flow tests and measuring steady state temperatures. Heat losses were estimated as ˜27%.

Experiments were performed for Reynolds number of 500 and 1000. Power input was limited to 14 and 21 kW/m² due to limitations in the capacity of the heather and the maximum desired temperature at the base of the test plates.

Tables 6 and 7 summarize the power input, average wall temperature and heat transfer coefficients for Re=500 and Re=1000, respectively. Steady state was declared when all temperatures in the data acquisition system remained within ±0.1 K for a 30 minutes period. Each test run took approximately 8 hours.

TABLE 6
Average Convective Heat Transfer Coefficient -
Experimental Results, Re = 500

| | Power | Average T_{wall} | H | Nu/Nu₀ |
|---|---|---|---|---|
| Model | (W/m²) | (K) | (W/m²K) | (h/h_{flat}) |
| Flat | 14000 | 324.01 | 8.68 | — |
| Circular | 14000 | 322.14 | 8.89 | 1.024 |
| Oval | 14000 | 320.77 | 9.58 | 1.104 |
| Flat | 21000 | 336.97 | 9.01 | — |
| Circular | 21000 | 335.88 | 9.00 | 0.999 |
| Oval | 21000 | 332.50 | 10.04 | 1.114 |

TABLE 7
Average Convective Heat Transfer Coefficient -
Experimental Results, Re = 1000

| | Power | Average | H | Nu/Nu₀ |
|---|---|---|---|---|
| Model | (W/m²) | T_{wall} (K) | (W/m²K) | (h/h_{flat}) |
| Flat | 14000 | 316.48 | 12.96 | — |
| Circular * | 14000 | 315.47 | 12.50 | 0.965 |
| Oval * | 14000 | 314.64 | 13.21 | 1.019 |
| Flat | 21000 | 327.15 | 12.68 | — |
| Circular | 21000 | 325.91 | 12.53 | 0.988 |
| Oval | 21000 | 323.60 | 13.54 | 1.068 |

For Reynolds number of 500, Table 6 shows heat transfer improvement in the oval dimple plate over the flat plate. Enhancement of 10.4% and 11.4% were observed in the oval dimple plate, as compared to the flat plate, for the power levels of 14 and 21 kW/m², respectively, while the circular dimple plate showed 2.4% and a reduction of 1% for the same power levels.

For Reynolds number of 1000, Table 7 suggests that heat transfer on dimpled surfaces reduces as the Reynolds number increases. Heat transfer improvement for the oval plate reduced from 11% (Re=500) to 1.9% and 6.8% (Re=1000), while the circular plate showed a consistent reduction in heat transfer when compared to the flat wall.

In summary, circular and oval dimpled plates showed improvement in average temperature over the flat plate, with a maximum of 3.7 K improvement (corrected by inlet temperature) in the oval dimple plate at Re=500 and power level of 21 kW/m².

### EXAMPLE 4

To quantify the potential improvement in thermal performance of dimpled heat sinks, numerical studies were conducted to determine the heat transfer and velocity profiles on a test plate or fin for laminar airflow in a rectangular channels. Due to symmetry in the flow direction, the numerical model was only solved for half of the channel and plate.

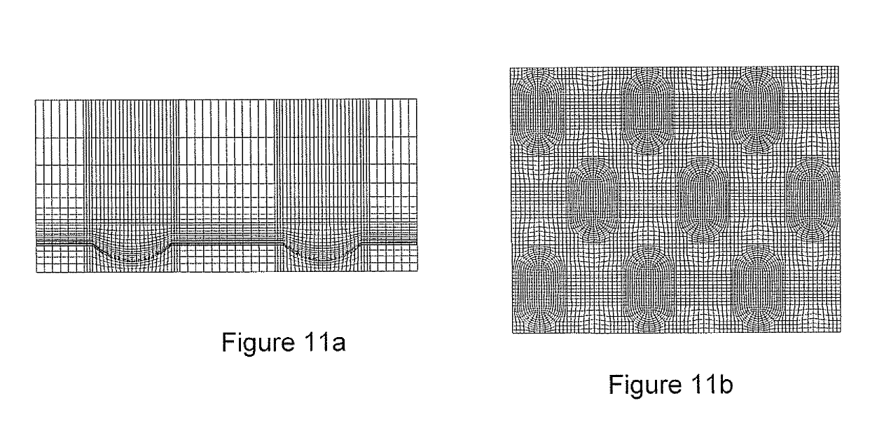

FIGS. 10a and 10b illustrate the side view and top view, respectively, of the computational grid used for the circular dimples. FIGS. 11a and 11b illustrate the side view and top view, respectively, of the computational grid used for the circular dimples. Hexahedral elements aligned with the flow direction were used to reduce the numerical dissipation errors and improve the quality of numerical predictions. Fine grids were employed for near-wall and dimpled surfaces to resolve the high gradients encountered in these region. The numbers of finite volume hexahedral cells employed for the entire flow domain and each region are shown in Table 8.

TABLE 8
Number of Finite Volume Cells for Each Domain

| | Inlet Region | Plate Region | Outlet Region | Total |
|---|---|---|---|---|
| Flat | 99,000 | 672,000 | 99,000 | 870,000 |
| Circular | 182,250 | 1,511,136 | 182,250 | 1,875,636 |
| Dimple | | | | |
| Oval Dimple | 207,900 | 1,738,044 | 207,900 | 2,153,844 |

The SIMPLE (Semi-Implicit Method for Pressure-Linked Equations) algorithm, along with a structured grid, was used to couple the pressure and velocity fields. The second-order upwind interpolation scheme and second-order spatial discretization scheme were used to reduce numerical errors.

Three different sets of grids were tested for grid independence of the circular and oval dimpled plates: 6×8, 8×13 and 10×16, depending on the number of elements inside the dimples For the 6×8 grid, a 1,219,488 plate element number was employed, for the 8×13 grid, a 1,995,296 plate element number was employed, and for the 10×16 grid, a 2,607,776 plate element number was employed. It was found that heat transfer prediction varied less than 2% with these grid selections. The Implicit Method was employed to the computational iteration. Scaled residuals were used for the convergence of the computational solutions for the continuity, energy, and for the other predicted variables. The setting criterion of the scaled residuals for the solution convergence was 1×10⁻³ for all computed residuals except for the energy equation 1×10⁻⁶.

FIGS. 7a-c illustrate the geometric details of the surfaces and dimples analyzed numerical with this model. FIG. 7a shows a flat plate with no dimples, FIG. 7b shows the circular dimpled plate with 11 by 22 dimples, and FIG. 7c shows the oval (elliptical) dimpled plate with 7 by 22 dimples on each side. The dimples were placed on both sides of the copper plate with a relative pitch S/D=1.21 and a relative depth δ/D=0.2 for the circular dimples. For the oval dimples, S/D=1.21 and δ/D=0.2 with same total depth and circular-edge-to-edge distance as the circular dimples. The test plates were modeled as copper.

Four different Reynolds numbers based on channel height, Re_{H} from 500 to 1650, with a uniform heat flux of 1.4×104 W/m² were used to simulate heat transfer coefficients, pressure drops, thermal performance, and flow characteristics of each modeled plate using FLUENT version 6.2.16.

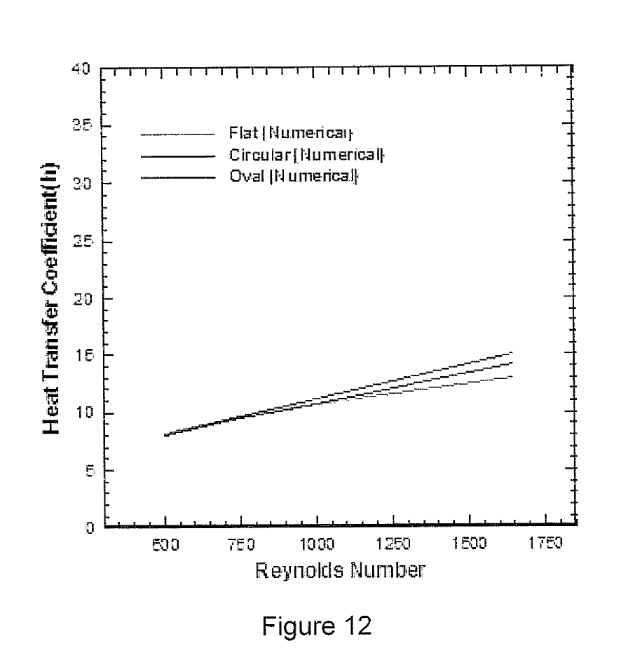

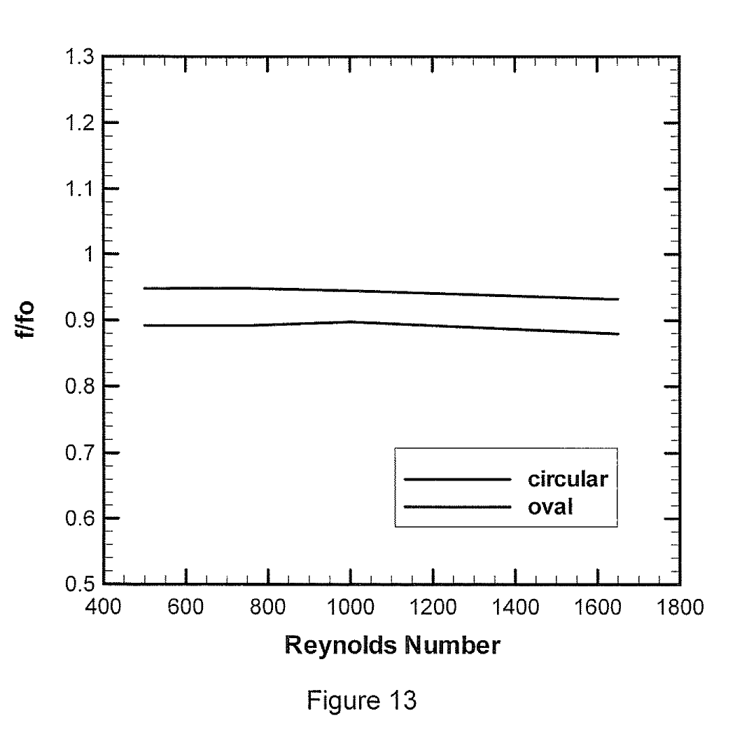

FIG. 12 shows the heat transfer coefficients comparison of numerical models for the four different Reynolds numbers of 500, 750, 1000, and 1650. FIG. 13 shows the friction factor ratio, f/f₀ for circular and oval type dimpled plates for the four different Reynolds numbers of 500, 750, 1000, and 1650. The pressure drops of the dimpled plates for a laminar airflow are either equivalent to, or less than values produced in the flat plate with no dimples. In the case of the circular dimpled plate, the friction factor ratio, f/f₀ was roughly 0.94. The fiction factor ratio, f/f₀ for the oval dimpled plate was roughly 0.89. The pressure drop for the oval type dimpled plate was smaller than that of the circular type dimpled plate.

The thermal performance factor was evaluated with Eq. 1 using the average Nusselt number ratio and the friction factor ratio. This parameter compares the heat transfer enhancement by dimples per unit pumping power relative to the heat transfer for the flat plate.
TP=(Nu/Nu₀)*(f/f₀)^{-1/3} Eq. 1

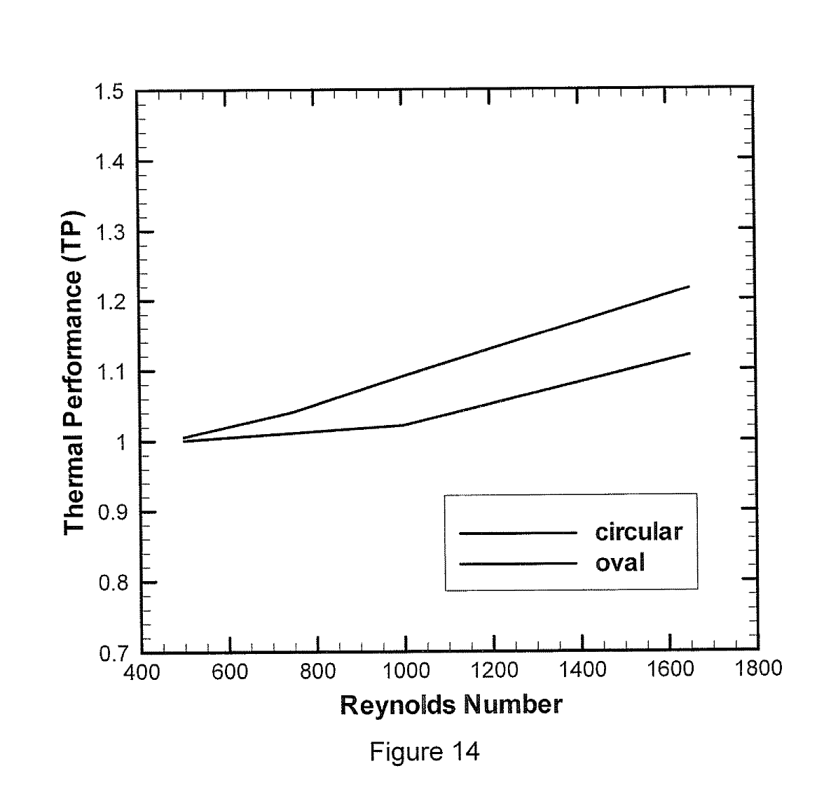

FIG. 14 compares the thermal performance factor for two different dimpled plates: circular and oval dimpled plate. Both cases showed that the thermal performance factor increases with increasing mass flow rate. The thermal performance factor for the oval dimpled plate increased from 1.0 to 1.21. The thermal performance factor for the circular dimpled plate increased from 1.0 to 1.12. The factor for the oval type dimpled plate was larger than that of the circular dimpled plate for all cases.

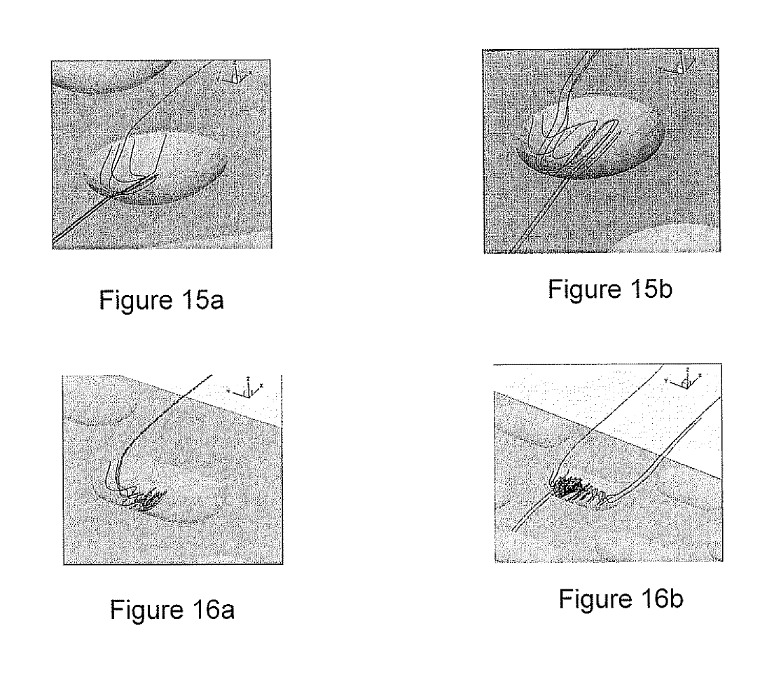

FIGS. 15a and b show the inside of the circular dimple for Re_{H}500 and Re_{H}11650, respectively, at the downstream region. FIGS. 16a and b show the inside of the oval dimple for Re_{H}500 and Re_{H}1650, respectively, at the downstream region. In general, higher intensity recirculation was shown for Re_{H} 1650 for both the circular and oval dimples as compared to the Re_{H} 500 case. Comparing the oval dimple and circular dimple, the larger recirculation inside of the dimple enhanced the flow mixing leading to the improved heat transfer.

In summary, the findings of this numerical study indicated that the pressure drops across the dimpled plates (circular and oval) for a laminar airflow are either equivalent to, or less than values produced in a flat plate with no dimples. Further, the pressure drop across the oval dimpled plate was smaller than that of the circular dimpled plate. In general, as the airflow velocity increased, the thermal performances of circular and oval plates increased; the thermal performance of the oval dimpled plate being generally greater than the circular dimpled plate.

While the use of dimples to enhance heat transfer (thermal performance) while minimizing friction factors and pressure drop have been described with reference to microelectronic components and systems, embodiments described herein may also be employed in a variety of suitable devices. Examples of such alternative applications include without limitation condensers or other finned heat exchange systems in Heating Ventilating and Air Conditioning (HVAC) systems, microchannel condensers and evaporators for high heat flux applications, space heaters having heated thin-walled plates that rely on laminar flow natural convection to heat the air in a room, etc. Further, in general, embodiments of the present invention may be employed in any application where it is desirable to reduce surface friction, including cyclists helmets, surfaces of race cars, reduction of form drag on sailboats, air bearings or journal bearings, and possibly laminar flow wings of some aircraft.

While preferred embodiments have been shown and described, modifications thereof can be made by one skilled in the art without departing from the scope or teachings herein. The embodiments described herein are exemplary only and are not limiting. Many variations and modifications of the system and apparatus are possible and are within the scope of the invention. For example, the relative dimensions of various parts, the materials from which the various parts are made, and other parameters can be varied. Accordingly, the scope of protection is not limited to the embodiments described herein, but is only limited by the claims that follow, the scope of which shall include all equivalents of the subject matter of the claims.

What is claimed is:

1. A heat sink for cooling a heated component comprising:
a base coupled to the component;
at least one thin-walled heat transfer member extending from the base, wherein the heat transfer member comprises an upstream end and a downstream end defined by a fluid flow direction, and a convective surface extending between the upstream end and the downstream end;
wherein the convective surface includes a recessed oval dimple having a major axis and a minor axis, wherein the oval dimple is oriented such that its major axis is at an angle θ relative to the fluid flow direction, wherein the angle θ is between 75° and less than 115°.

2. The heat sink of claim 1 wherein the angle θ is about 90°.

3. The heat sink of claim 2 wherein the oval dimple comprises a pair of opposing semi-circular ends and a rectangular mid-section extending therebetween, wherein each semi-circular end has a diameter D, the diameter D of each semi-circular end being substantially the same.

4. The heat sink of claim 3 wherein the oval dimple has a dimple depth δ, wherein the ratio of the dimple depth δ to the diameter D is between 0.18 and 0.24.

5. The heat sink of claim 4 wherein the ratio of the dimple depth δ to the diameter D is about 0.20.

6. The heat sink of claim 1 wherein the heat transfer member comprises a fixed end coupled to the base and a free end distal the base, and wherein the convective surface of the heat transfer member further comprises:
a first plurality of oval dimples arranged in a first row extending linearly between the fixed end and the free end along a first median line that is substantially perpendicular to the fluid flow direction;
a second plurality of oval dimples arranged in a second row extending linearly between the fixed end and the free end along a second medial line that is substantially parallel with the first median line;
wherein each oval dimple has a major axis and a minor axis, and wherein each of the first plurality of oval dimples is oriented with its major axis aligned with the first median line, and wherein each of the second plurality of oval dimples is oriented with its major axis aligned with the second median line.

7. The heat sink of claim 6 wherein each oval dimple comprises a pair of opposing semi-circular ends and a rectangular mid-section extending therebetween, wherein each semi-circular end has a center of curvature and a diameter D, the diameter D of each semi-circular end being substantially the same.

8. The heat sink of claim 7 wherein the second row is spaced apart from the first row by an inter-row pitch Sᵢ measured perpendicularly between the first median line and the second median line, wherein the ratio of the inter-row pitch Sᵢ to the diameter D is between 0.80 and 2.00.

9. The heat sink of claim 8 wherein the ratio of the inter-row pitch Sᵢ to the diameter D is about 1.21.

10. The heat sink of claim 8 wherein the dimples in the first row are spaced apart by a uniform distance V₁ measured along the first median line between the adjacent dimples in the first row, and the dimples in the second row are spaced apart by a uniform distance V₂ measured along the second median line between adjacent dimples in the second row, and wherein distance V₁ and distance V₂ are substantially the same.

11. The heat sink of claim 8 wherein each dimple in the second row is offset from an adjacent dimple in the first row by a uniform offset pitch Sₒ measured parallel to the first median line between the centers of curvature of the proximal semi-circular ends of the adjacent dimples in the first and second rows, wherein the ratio of the offset pitch Sₒ to the diameter D is between 0.80 and 2.00.

12. The heat sink of claim 11 wherein the offset pitch Sₒ is substantially the same as the inter-row pitch Sᵢ.

13. The heat sink of claim 11 wherein the ratio of the offset pitch Sₒ to the diameter D is about 1.21.

14. The heat sink of claim 12 wherein each oval dimple has a dimple depth δ, wherein the ratio of the dimple depth δ to the diameter D is between 0.18 and 0.24.

15. The heat sink of claim 14 wherein the ratio of the dimple depth δ to the diameter D is about 0.20.

16. A method for transferring thermal energy comprising:
providing a thin-walled heat transfer member having an upstream end, a downstream end, and a convective surface extending therebetween;
forming a plurality of recessed oval dimples in the convective surface of the heat transfer member, wherein each oval dimple has a major axis and a minor axis;
heating the heat transfer member;
flowing a fluid at a Reynolds number between 350 and 1000 in a flow direction over the convective surface from the upstream end towards the downstream end; and
positioning each oval dimple such that its major axis is oriented at an angle θ relative to the flow direction, wherein the angle θ is between 75° and 115°.

17. The method of claim 16 wherein the angle θ is about 90°.

18. The method of claim 16 wherein each oval dimple has opposing semi-circular ends and a rectangular mid-section extending therebetween, wherein each semi-circular end has a center of curvature and a diameter D, the diameter D of each semi-circular end being substantially the same.

19. The method of claim 18 wherein each oval dimple has a dimple depth δ, wherein the ratio of the dimple depth δ to the diameter D is between 0.18 and 0.22.

20. The method of claim 19 further comprising:
positioning a first plurality of oval dimples in a first row extending linearly along a first median line that is substantially perpendicular to the flow direction;
positioning a second plurality of oval dimples in a second row extending along a second median line flat is substantially parallel with the first median line.

21. The method of claim 19 further comprising spacing the first row from the second row by an inter-row pitch Sᵢ measured perpendicular between the first median line and the second median line, wherein the ratio of the inter-row pitch Sᵢ and the diameter D is between 0.80 and 2.00

22. The method of claim 21 further comprising spacing the oval dimples in the first row by a distance V₁ measured along the first median line between adjacent dimples in the first row, and spacing the oval dimples in the second row by a distance V₂ measured along the second median line between adjacent dimples in the second row, wherein the distance V₁ is equal to the distance V₂.

23. The method of claim 22 further comprising staggering the dimples in the second row relative to the dimples in the first row by an offset pitch Sₒ measured parallel to the first median line between the centers of curvature of the proximal semi-circular ends of the adjacent dimples in the first and second rows, wherein the ratio of the offset pitch Sₒ to the diameter D is between 0.80 and 2.00.

24. The method of claim 23 wherein the inter-row pitch Sᵢ is equal to the offset pitch Sₒ.
